(19) United States
(12) Patent Application Publication
(10) Pub. No.: US 2006/0213551 A1
(43) Pub. Date: Sep. 28, 2006

(54) Semiconductor photodetector and method for manufacturing same

(75) Inventor: Hoger Hoehnemann, Leingarten (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/386,932

(22) Filed: Mar. 23, 2006

(30) Foreign Application Priority Data
Mar. 24, 2005 (DE) 102005013640.0-33

(51) Int. Cl. H01L 31/00

(52) U.S. Cl. 136/255

(57) ABSTRACT

A semiconductor photodetector and method for producing the semiconductor photodetector are provided that includes a semiconductor substrate; semiconductor areas provided above the semiconductor substrate that have suitable dopings to form a space-charge zone for detecting electromagnetic radiation incident from above; at least two semiconductor mirror layers having different refractive indices are provided between the space-charge zone and semiconductor substrate to form a Bragg reflector for reflecting the radiation to be detected in the direction of the space-charge zone.

This nonprovisional application claims priority under 35 U.S.C. § 119(a) on German Patent Application No. DE 10200501364.0-33, which was filed in Germany on Mar. 24, 2005, and which is herein incorporated by reference.

### BACKGROUND OF THE INVENTION

1. Field of the Invention

The present invention relates to a semiconductor photodetector and a method for manufacturing a photodetector.

2. Description of the Background Art

Photodetectors are generally used to convert electromagnetic radiation to an electric current or voltage signal. Depending on the type of interaction involved between light and matter, a distinction is made between direct and indirect optoelectronic signal conversion.

In general, when light strikes matter, the individual light quanta, i.e. the individual photons, can transfer their energy to the electrons present in the matter. In doing this, for example, the energy can raise the electrons of the valence transition of a semiconductor to the conduction band, which is known as the inner photo effect, where they are able to move freely and result in an increase in the electric conductivity of the semiconductor. If the inner photo effect occurs in the depletion region of the p-n junction of a semiconductor acting as the depletion layer, an independent photoelectric voltage is produced which proves to be equivalent to the difference between the voltage drops in the reverse and forward directions. This effect is utilized in photodetectors, where the light energy is converted to electric energy.

The electrons released by the incident light radiation, or the holes left behind, migrate to allocated regions, an electric voltage forming between these regions which can be tapped at allocated terminal areas and which can produce a current flow in an outer circuit.

In a semiconductor photodetector, the incident light interacts with the quasifree electrons of the semiconductor material and generates, directly through the photoelectric effect, an electric output signal which is dependent on the incident light energy. The photon absorption influences the electrical performance in the area of what is known as the space-charge zone of semiconductor photodetectors. The incident light here is at least partially absorbed in the space-charge zone and converted to electrons and holes (O/E conversion). These electrons and holes supply a measurable voltage or current signal as a measure of the incident or absorbed radiation.

During optoelectronic signal conversion, the greatest possible efficiency, in particular, is desirable in the required spectral operating range, i.e., the photodetector should have a high quantum efficiency. The photodetector should also have a high operating speed, i.e., it should ensure uncorrupted reproduction of the received light signals at high modulation frequencies.

Generally, silicon photodectors are made of a p-type silicon single crystal which is doped with an n-type zone. This forms a depletion layer, in which, in the presence of incident light radiation, the depletion layer-free region of the n-type zone can act as a negative pole of the photodetector and the depletion layer-free region of the p-type zone as a positive pole.

FIG. 1 illustrates a cross-sectional view of a conventional semiconductor photodetector. As shown in FIG. 1, a first doped region 4 and a second doped region 6 are provided in substrate 1 in such a way that a space-charge zone 5 forms. For example, if near infrared light 7 strikes space-charge zone 5, radiation 7 interacts with the matter of space-charge zone 5, space-charge zone 5 having to be designed with a relatively great thickness to be able to utilize a large portion of incident light 7.

This approach has proven to be disadvantageous in that the remainder of radiation 7 not interacting in the space-charge zone may interact with substrate 1 and produce stray charge carriers. However, these charge carriers produced outside the space-charge zone have a disadvantageous effect on the generated output signal, since when the generated current or the generated voltage is tapped, these charge carriers are also undesirably captured, and the edges of the optical signal are rounded or weakened.

The aforementioned approach according to the conventional art has further proven to be disadvantageous in that the efficiency of a photodetector constructed in such a manner is satisfactory only if the space-charge zone is designed to have a sufficiently great thickness.

### SUMMARY OF THE INVENTION

It is therefore an object of the present invention to provide a semiconductor photodetector having an improved quantum efficiency, reduced generation of stray charge carriers, and a smaller construction and also to provide a method for manufacturing a semiconductor photodetector of this type.

The semiconductor photodetector includes a semiconductor substrate and semiconductor zones provided above the semiconductor substrate which have suitable dopings to form a space-charge zone for detecting electromagnetic radiation incident from above, at least two semiconductor mirror layers having different refractive indices being provided between the space-charge zone and the semiconductor substrate to form a distributed Bragg reflector for reflecting the radiation to be detected in the direction of the space-charge zone.

The radiation striking the space-charge zone and not interacting with the space-charge zone is thus reflected back in the direction of the space-charge zone by a reflection on the Bragg semiconductor layers, so that this radiation may again interact with the space-charge zone.

Compared to the conventional art, the present invention therefore has the advantage that the light to be detected passes through the space-charge zone twice, i.e., twice as often, and thus substantially increases the quantum efficiency.

This also advantageously prevents the radiation, which is not interacting with the matter of the space-charge zone, from producing stray charge carriers in the substrate, since the radiation does not pass through the semiconductor substrate due to the reflection on the semiconductor mirror layers.

In addition, for example, the thickness of the detector layer or the space-charge zone may be reduced to achieve a predetermined efficiency, since, due to the dual path of the radiation to be detected through the space-charge zone, the quantum efficiency is increased as explained above.

According to an embodiment, the semiconductor substrate is designed as a silicon substrate. A heavily p-doped silicon substrate is preferably used. Other suitable substrate materials can also be used.

According to a further embodiment, at least two semiconductor mirror layers are provided substantially directly beneath the space-charge zone. This ensures that the radiation not interacting with the matter of the space-charge zone does not undesirably produce stray charge carriers in the region of the substrate, since the radiation preferably passes between the space-charge zone and the semiconductor mirror layers and does not pass through the substrate. This improves the measuring signal and guarantees a more reliable radiation measurement.

At least one layer sequence which includes a silicon-germanium mirror layer having a higher refractive index and one silicon mirror layer having a lower refractive index can be provided on the semiconductor substrate. For example, approximately three to seven layer sequences of this type may be applied to the semiconductor substrate. Also, any number of layer sequences is possible, depending on the application.

According to a further embodiment, the silicon-germanium and silicon mirror layers can each be grown epitactically onto the silicon substrate in the form of thin layers having a thickness of, for example, 40 nm to 80 nm. An epitaxial deposition of this type ensures a small number of defects and reduces manufacturing costs.

The thickness and refractive index in each case, and/or the number of individual semiconductor mirror layers, are preferably adjusted to the wavelength of the radiation to be detected and/or the desired efficiency.

According to a further embodiment, the space-charge zone is grown epitaxially in the form of a lightly p-doped silicon region. This, in turn, is a common, simple and cost-effective method to be carried out, one which has a low probability of defects.

Boron is preferably used as the dopant for the p-doping. However, other suitable dopants may also be used.

An n-doped silicon region is preferably provided above the space-charge zone. Phosphorus, arsenic or a similar material is preferably used as the dopant for the n-doped silicon region. However, other suitable dopants may also be used.

According to yet a further embodiment, suitable electric terminal areas are provided for tapping the voltage generated by the incident radiation to be detected. For example, one electrode may be provided in a suitable manner on the n-doped silicon region and another electrode on the underside of the substrate.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic cross-sectional view of a conventional semiconductor photodetector; and

FIG. 2 is a schematic cross-sectional view of a semiconductor photodetector according to an embodiment of the present invention.

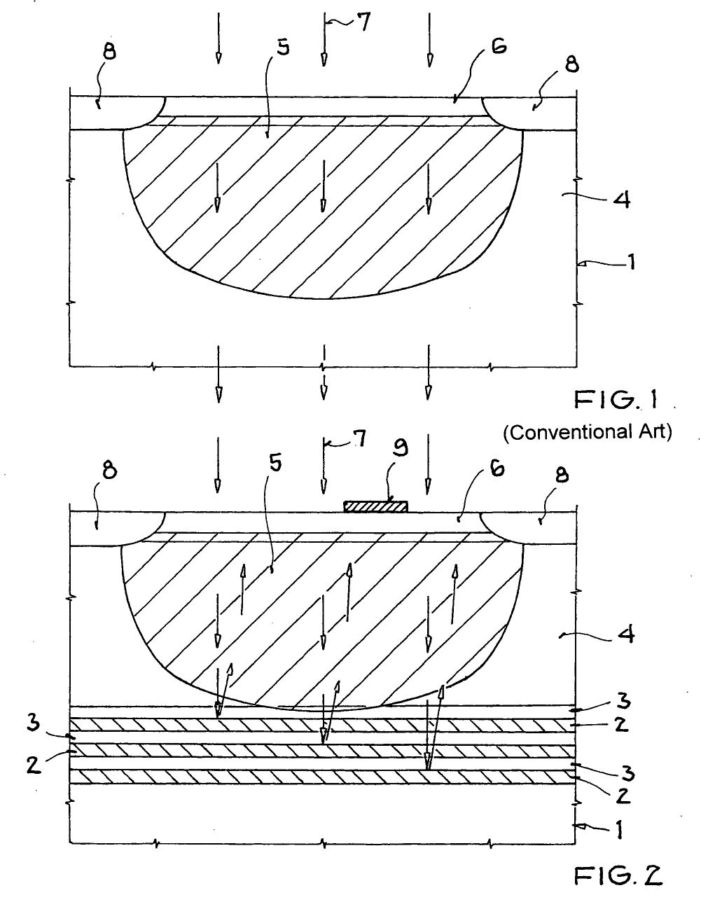

### DETAILED DESCRIPTION

Unless otherwise specified, the same reference symbols in the figures designate equivalent or functionally equivalent components.

FIG. 2 illustrates a schematic cross-sectional view of a semiconductor photodetector according to an embodiment of the present invention.

As shown in FIG. 2, a first semiconductor mirror layer 2 having a first refractive index is applied, for example, to a silicon substrate 1. For example, a silicon-germanium layer 2 is grown epitaxially in a thin layer on the silicon substrate 1 as a first semiconductor mirror layer 2. The thickness of the silicon-germanium layer 2 is, for example, 40 nm to 80 nm, and it is preferably adjusted to the wavelength of radiation 7 to be detected and to the thickness and the refractive index of an additional semiconductor mirror layer 3.

The refractive index of silicon-germanium layer 2 may be controlled by the germanium concentration, a higher proportion of germanium producing a higher refractive index of silicon-germanium layer 2. In selecting the proportion of germanium in silicon-germanium layer 2, a compromise must be made between a higher refractive index at an elevated proportion of germanium and a greater silicon lattice distortion, in which case a greater number of defects is to be expected.

The growth process is preferably carried out by a common epitaxial growth method which represents a simple and cost-effective method.

As is further shown in FIG. 2, a second semiconductor mirror layer 3 is subsequently applied to silicon-germanium layer 2. For example, second semiconductor mirror layer 3 is designed as silicon layer 3 and also has a thickness of preferably 40 nm to 80 nm. Silicon layer 3 has a lower refractive index than silicon-germanium layer 2, so that a ray path is Bragg-reflected on the junction between silicon layer 3 and silicon-germanium layer 2. The layer sequence comprising silicon-germanium layer 2 and silicon mirror layer 3 thus forms a Bragg reflector for incident radiation 7 to be detected.

Multiple layer sequences of this type, comprising a silicon-germanium layer 2 and a silicon layer 3 may be applied consecutively to silicon substrate 1. In the embodiment shown in FIG. 2, three of these layer sequences are illustrated by way of example.

The number of layer sequences, the thickness of individual Bragg layers 2 and 3 as well as the refractive index are preferably adjusted to the wavelength of radiation 7 to be detected. In this case, the reflectance with regard to radiation 7 to be detected should be as high as possible so that the largest possible amount of radiation 7 follows a dual path through the space-charge zone represented by reference symbol 5.

Like silicon-germanium layer 2, silicon layer 3 is preferably grown on silicon-germanium layer 2, using a common epitaxial method. Other methods are, of course, also conceivable.

As is further shown in FIG. 2, a suitably doped intrinsic silicon layer 4 is epitaxially grown directly above the Bragg layer sequence comprising layers 2 and 3 in such a way that space-charge zone 5 is preferably able to form directly over Bragg layers 2 and 3. The advantage of intrinsic layers of this type is that they have an extremely small number of defects.

For example, silicon substrate 1 is designed as a heavily p-doped silicon substrate and intrinsic silicon layer 4 as a lightly p-doped silicon layer. In this case, boron or a similarly suitable material may be used as the p-dopant.

An n-doped silicon layer 6 is subsequently formed on lightly p-doped silicon layer 4, for example, using a common implantation or diffusion method. Phosphorus, arsenic or a similar material may be used as the dopant in this case.

The dopings of silicon layers 4 and 6 are selected in such a way that the aforementioned space-charge zone 5 forms in which incident radiation 7 interacts with the matter in such a way that charge carriers or holes are produced to generate an electric voltage or an electric current. This generated voltage may be tapped via suitable terminal areas 8, 9.

The present invention thus provides a semiconductor photodetector in which the proportion of stray charge carriers may be substantially reduced due to the integration of one or more mirror layers to form a Bragg reflector between the substrate 1 and detector layer 5. Furthermore, the thickness of detector layer 5 may also be reduced, since radiation 7 to be detected passes through space-charge zone 5 twice due to the reflection on Bragg layers 2 and 3, thereby increasing the quantum efficiency.

In the photodetector according to the invention, the layers also advantageously require a low germanium concentration to achieve an adequately differentiated refractive index, so that excessively high stresses do not occur in the silicon lattice as a result of the germanium concentration.

In addition, the stacked layer structures according to the invention are extremely stable with respect to high-temperature processes, so that photodetectors of this type may be implemented easily and cost-effectively in current high-temperature processes.

The semiconductor photodetector described above may be used, for example, to detect a near infrared light or an electromagnetic radiation having a wavelength of 700 nm and 1,100 nm. However, it is obvious to those skilled in the art that the inventive idea described above is applicable, in principle, to all radiations across the total wavelength range. The efficiency of the photodetector according to the invention is dependent on the number of layer sequences, the materials selected, the corresponding refractive indices and the layer thicknesses selected.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor photodetector comprising:
a semiconductor substrate;
semiconductor areas provided above the semiconductor substrate, having dopings to form a space-charge zone for detecting electromagnetic radiation; and
at least two semiconductor mirror layers having different refractive indices are provided between the space-charge zone and the semiconductor substrate to form a Bragg reflector for reflecting the radiation that is to be detected towards the space-charge zone.

2. The Semiconductor photodetector according to claim 1, wherein the semiconductor substrate is a silicon substrate or a heavily p-doped silicon substrate.

3. The semiconductor photodetector according to claim 1, wherein the at least two semiconductor mirror layers are provided directly below the space-charge zone.

4. The semiconductor photodetector according to claim 1, further comprising at least one layer sequence, which includes the silicon-germanium mirror layer having a higher refractive index and a silicon mirror layer having a lower refractive index, is provided on the semiconductor substrate.

5. The semiconductor photodetector according to claim 4, wherein three to seven of the layer sequences are provided on the semiconductor substrate.

6. Semiconductor photodetector according to claim 4, wherein the silicon-germanium mirror layer and the silicon mirror layer are each grown on the silicon substrate in layers having a thickness of 40 nm to 80 nm.

7. The semiconductor photodetector according to claim 1, wherein a thickness, a refractive index and/or a number of individual semiconductor mirror layers are each adjusted to a wavelength of the radiation to be detected and/or to an efficiency of the photodetector.

8. The semiconductor photodetector according to claim 1, wherein the space-charge zone is a lightly p-doped silicon region or an epitaxially applied intrinsic silicon layer.

9. The semiconductor photodetector according to claim 8, wherein the p-dopant is boron or a similar material.

10. The semiconductor photodetector according to claim 1, wherein an n-doped silicon region is provided above the space-charge zone.

11. The semiconductor photodetector according to claim 10, wherein the n-dopant is phosphorus, arsenic, or a similar material.

12. The semiconductor photodetector according to claim 1, further comprising electric terminal areas for tapping an electric voltage produced by the incident radiation.

13. A method for manufacturing a semiconductor photodetector, the method comprising the steps of:
providing a semiconductor substrate;
forming semiconductor regions above the semiconductor substrate, the semiconductor regions having suitable dopings to form a space-charge zone for detecting electromagnetic radiation incident from above; and
forming at least two semiconductor mirror layers having different refractive indices between the space-charge zone and the semiconductor substrate to form a Bragg reflector for reflecting radiation, which is to be detected, in a direction towards the space-charge zone.

14. The method according to claim 13, wherein the semiconductor substrate is a silicon substrate or a heavily p-doped silicon substrate.

15. The method according to claim 13, wherein the at least two semiconductor layers are formed directly below the space-charge zone.

16. The method according to claim 13, wherein at least one layer sequence, including a silicon-germanium mirror layer having a higher refractive index and a silicon mirror layer having a lower refractive index, is formed on the semiconductor substrate.

17. The method according to claim 16, wherein three to seven layer sequences are formed on the semiconductor substrate.

18. The method according to claim 16, wherein the silicon-germanium mirror layer and the silicon mirror layer are each grown on the silicon substrate in layers having a thickness of 40 nm to 80 nm.

19. The method according to claim 13, wherein a thickness, a refractive index and/or a number of individual semiconductor mirror layers are each adjusted to a wavelength of the radiation to be detected and/or to an efficiency of the photodetector.

20. The method according to claim 13, wherein the space-charge zone is a p-doped silicon region or an epitaxially applied intrinsic silicon layer.

21. The method according to claim 20, wherein the p-dopant is boron or a similar material.

22. The method according to claims 13, wherein an n-doped silicon region is formed above the space-charge zone.

23. The method according to claim 22, wherein phosphorus, arsenic or a similar material is used as the n-dopant.

24. The method according to claim 13, wherein electric terminal areas are provided for tapping electric voltages generated by the incident radiation to be detected.
